(19) United States
(12) Patent Application Publication
(10) Pub. No.: US 2026/0096477 A1
(43) Pub. Date: Apr. 2, 2026

(54) PACKAGE STRUCTURE AND METHOD OF FORMING THE SAME

(71) Applicant: Taiwan Semiconductor Manufacturing Company, Ltd., Hsinchu (TW)

(72) Inventors: Hung-Yi Kuo, Taipei City (TW); Hao-Yi Tsai, Hsinchu City (TW); Ming-Hung Tseng, Miaoli County (TW); Yu-Min Liang, Taoyuan City (TW); Chia-Yen Tan, Taoyuan City (TW)

(73) Assignee: Taiwan Semiconductor Manufacturing Company, Ltd., Hsinchu (TW)

(21) Appl. No.: 18/904,054

(22) Filed: Oct. 1, 2024

(51) Int. Cl. H01L 25/16; G02B 6/42; H01L 23/00; H01L 23/29; H01L 23/31; H01L 23/367

(52) U.S. Cl. CPC H10W 90/00; G02B 6/4239; G02B 6/4269; G02B 6/4278; H10W 40/226; H10W 74/117; H10W 74/127; H10W 74/473; H10W 90/22; H10W 90/724

(57) ABSTRACT

Provided is a package structure including a first tier, a second tier, and a cladding layer. The first tier has a first surface and a second surface opposite to each other. The second tier is bonded to the second surface of the first tier by a plurality of conductive connectors. The cladding layer is disposed between the first tier and the second tier. The cladding layer has inner sidewalls to define a groove for accommodating the plurality of conductive connectors, and the inner sidewalls are inclined sidewalls.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1J illustrate cross-sectional views of intermediate stages in the formation of a package structure in accordance with some embodiments.

FIG. 2 illustrates a cross-sectional view of an integrated circuit die in accordance with some embodiments.

FIG. 3 illustrates a cross-sectional view of an integrated circuit die in accordance with some alternative embodiments.

FIG. 4 illustrates a cross-sectional view of an integrated circuit die in accordance with some other embodiments.

FIG. 5A to FIG. 5D illustrate cross-sectional views of intermediate stages in the formation of a package structure in accordance with some alternative embodiments.

FIG. 6 illustrates a cross-sectional view of a package structure in accordance with some other embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

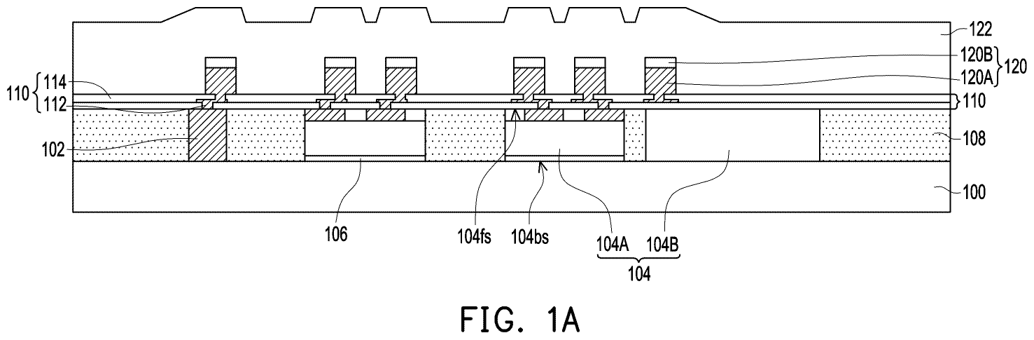

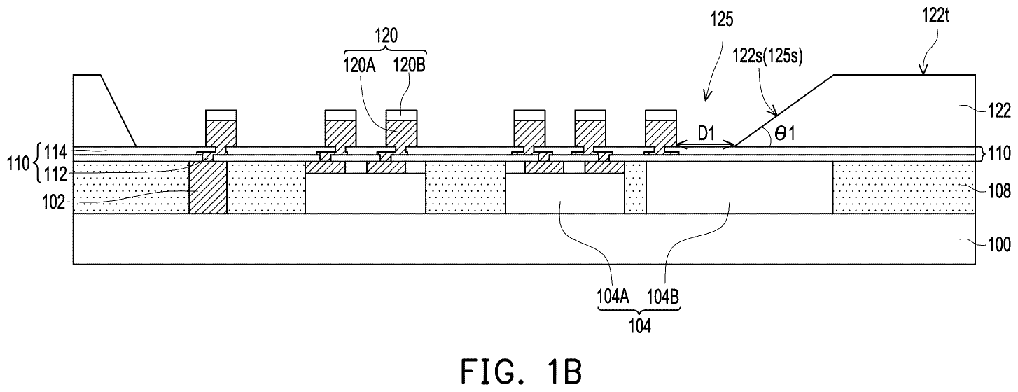

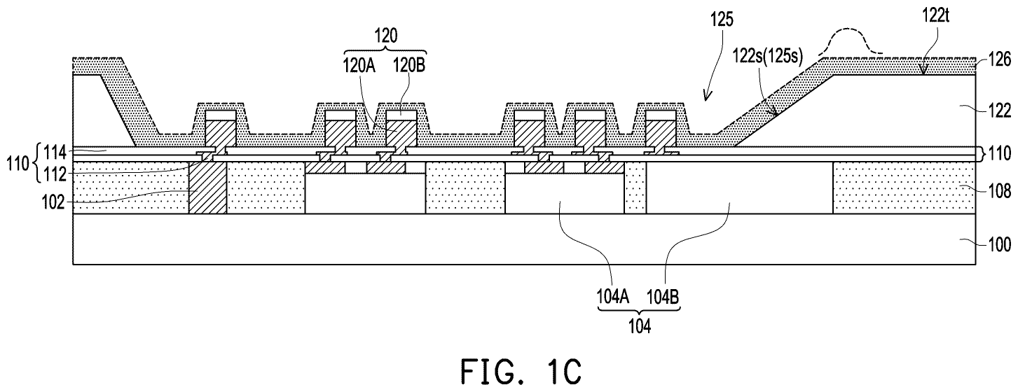

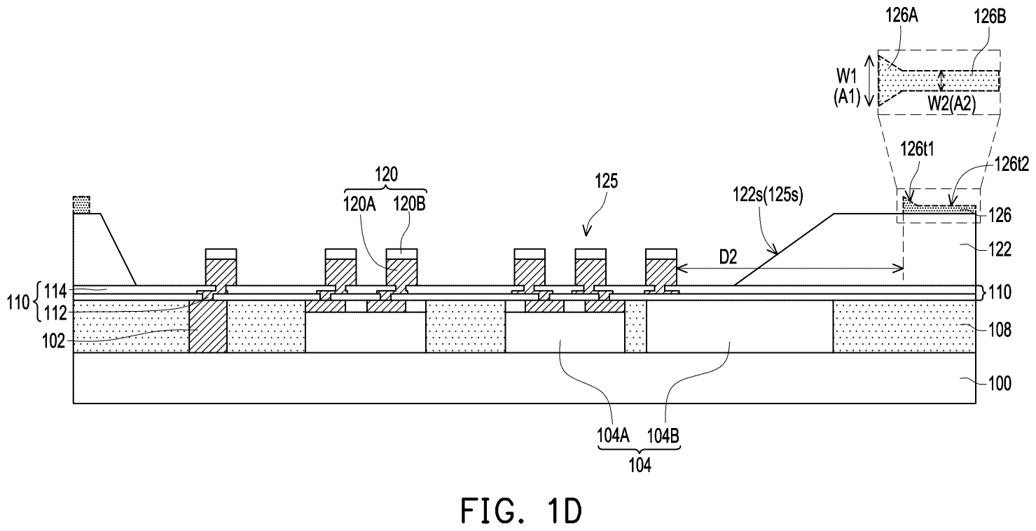

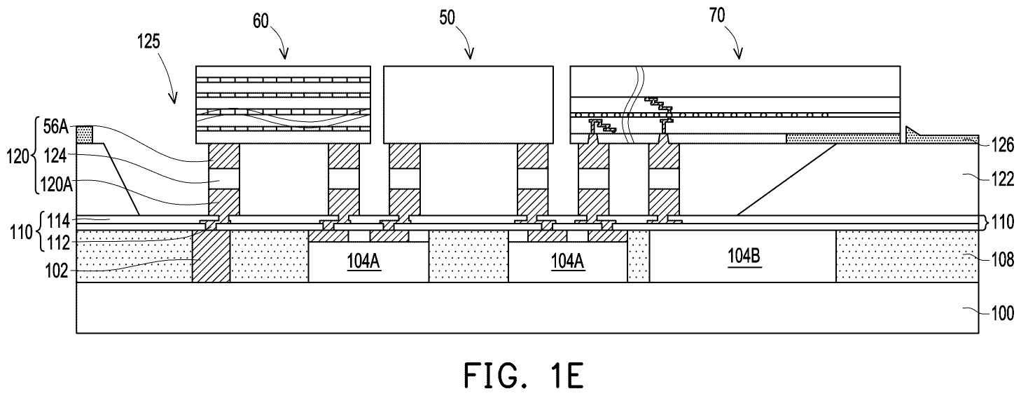

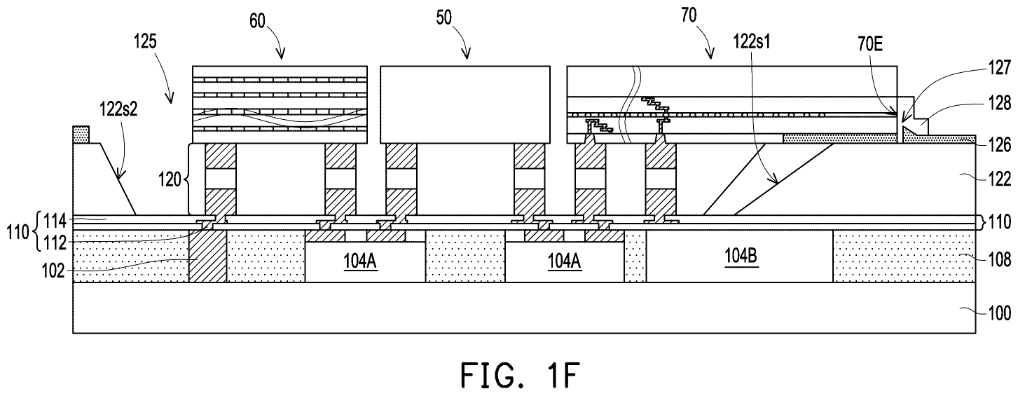

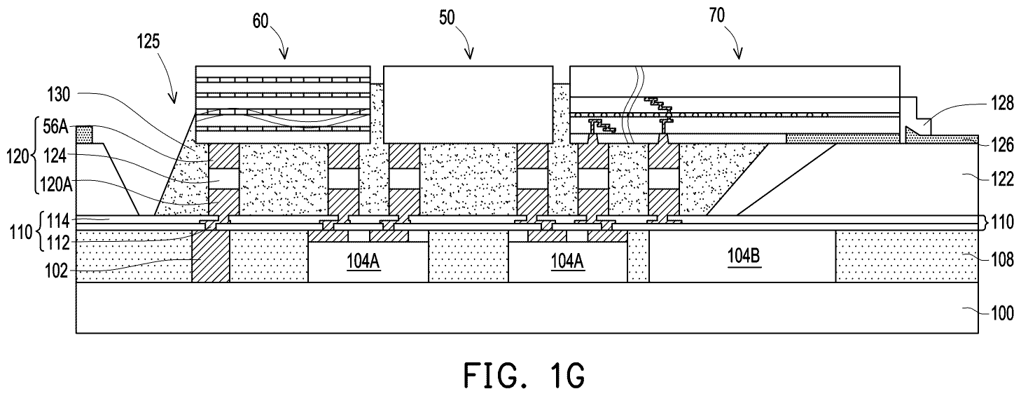

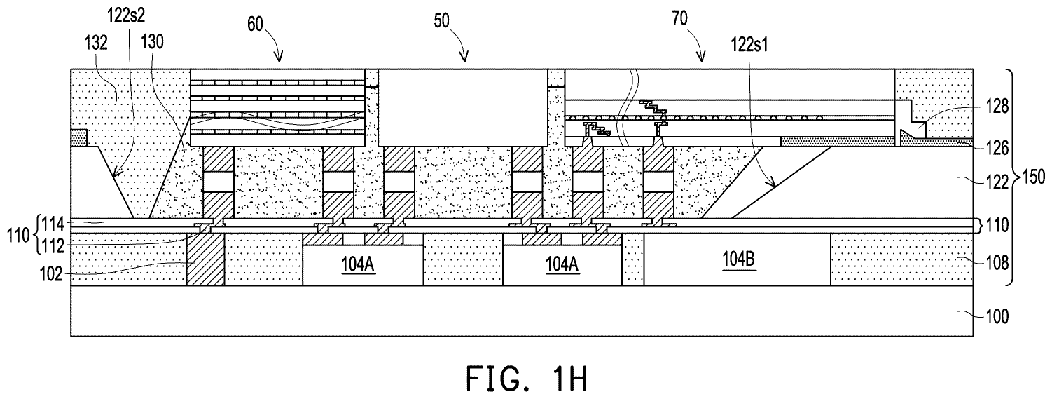

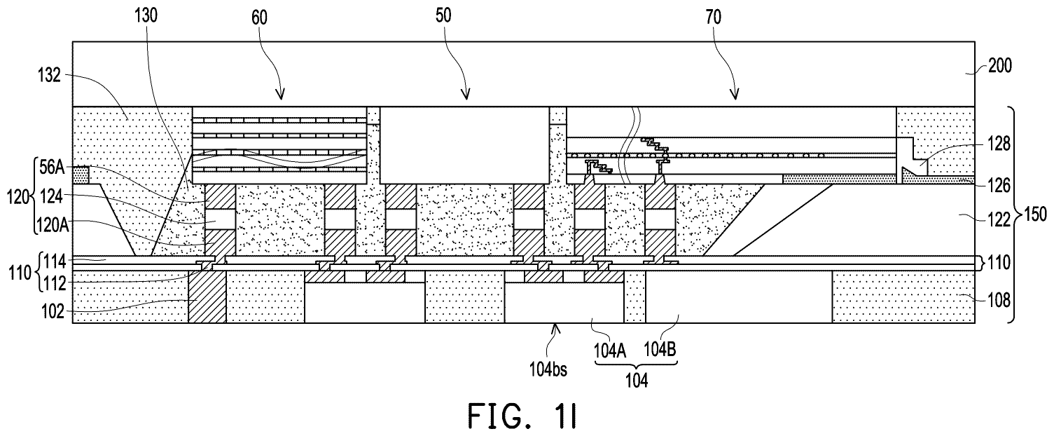

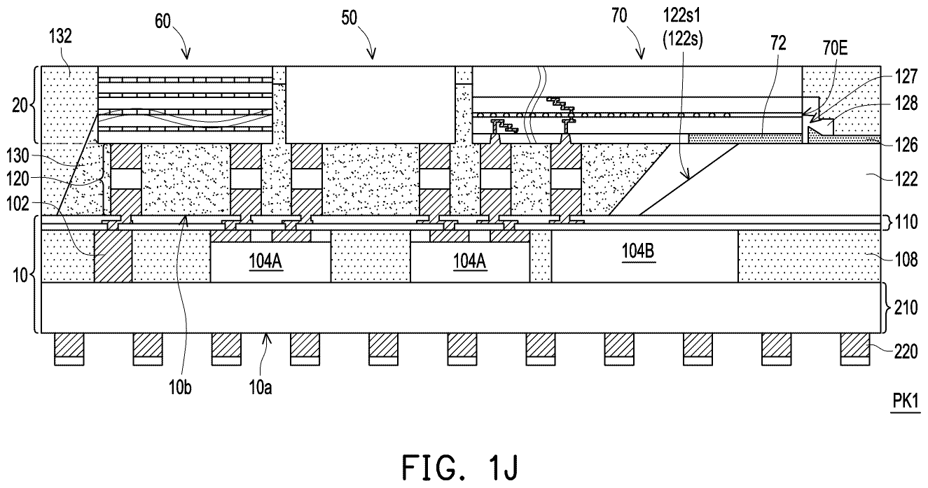

FIG. 1A to FIG. 1J illustrate cross-sectional views of intermediate stages in the formation of a package structure in accordance with some embodiments.

Referring to FIG. 1A, a first carrier 100 is provided or formed. The first carrier 100 is used as a platform or a support for a packaging process described below. In some embodiments, the first carrier 100 comprises a semiconductor material (such as silicon, or the like), a dielectric material (such as glass, a ceramic material, quartz, or the like), a combination thereof, or the like.

In some embodiments, one or more conductive vias 102 are formed on the first carrier 100. The conductive vias 102 may be also referred to as through vias, through molding vias, or through encapsulant vias. As an example to form the conductive vias 102, a seed layer (not shown) is formed over the first carrier 100. In some embodiments, the seed layer is a metal layer, which may be a single layer or a composite layer comprising a plurality of sub-layers formed of different materials. In a particular embodiment, the seed layer comprises a titanium layer and a copper layer over the titanium layer. The seed layer may be formed using, for example, PVD or the like. A photoresist is formed and patterned on the seed layer. The photoresist may be formed by spin coating or the like and may be exposed to light for patterning. The pattern of the photoresist corresponds to conductive vias. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the conductive vias 102.

In some embodiments, one or more dies 104 are attached to the first carrier 100. One of the dies 104 may be a local silicon interconnect (LSI) die 104A to interconnect at least two dies of overlying integrated circuit dies 50, 60, and 70 (FIG. 1E), thereby allowing for greater die-to-die routing capacity. That is, compared with the conventional redistribution lines (RDLs), the LSI die 104A has the greater routing density and transmission speed to achieve good bandwidth (BW) scalability and chip miniaturization. In addition, the other of the dies 104 may be a dummy die 104B, which can provide better warpage control to the package structure. In one embodiment, the size (e.g., width, height and/or shape) of the LSI die 104A is substantially identical to the size (e.g., width, height and/or shape) of the dummy dies 104B. In an alternative embodiment, the size (e.g., width, height and/or shape) of the LSI die 104A is different from the size (e.g., width, height and/or shape) of the dummy dies 104B.

In some alternative embodiments, the LSI die 104A also has other functions other than interconnection. For example, the LSI die 104A may have active and/or passive components, such as diodes, transistors, image sensors, capacitors, resistors, and so on. In some alternative embodiments, the LSI die 104A includes a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

In some embodiments, a backside 104bs of the LSI die 104A is attached to the first carrier 100, so that a frontside 104fs (such as sides on which electrical device and conducive interconnects are formed) of the LSI die 104A faces away from the first carrier 100. In some embodiments, the LSI die 104A is attached to the first carrier 100 by using an adhesive 106. The adhesive 106 may be any suitable adhesive, epoxy, die attach film (DAF), or the like. The adhesive 106 may be applied to the backside 104bs of the LSI die 104A or may be applied over a surface of the first carrier 100.

In some embodiments, an encapsulant 108 is formed to laterally encapsulate the dies 104 and the conductive vias 102. The encapsulant 108 may be a molding compound, epoxy, or the like. The encapsulant 108 may be applied by compression molding, transfer molding, or the like, and is formed over the first carrier 100, so that the dies 104 and the conductive vias 102 are buried or covered. The encapsulant 108 may be applied in liquid or semi-liquid form and then subsequently cured. The encapsulant 108 may be thinned to expose the dies 104. The thinning process may be a grinding process, a chemical mechanical polishing (CMP), an etch-back, combinations thereof, or the like. After the thinning process, the frontside 104fs of the dies 104, the top surface of the conductive vias 102, and a top surface of the encapsulant 108 are coplanar (within process variations), so that they are level with one another. The thinning is performed until a desired amount of the dies 104, the encapsulant 108, and/or the conductive vias 102 has been removed.

After the thinning process, a redistribution structure 110 is formed over the frontside 104fs of the dies 104, the encapsulant 108, and the conductive vias 102. In the embodiment shown, the redistribution structure 110 includes insulating layers 114 and metallization patterns 112 alternately disposed over the dies 104, the encapsulant 108, and the conductive vias 102. The insulating layers 114 may be formed of a photo-sensitive material (such as PBO, polyimide, BCB, or the like) or a non-photo-sensitive material (such as silicon oxide, silicon nitride, or the like). The insulating layers 114 may be formed by spin coating, lamination, CVD, the like, or a combination thereof, and may be patterned by exposing and developing processes or etching processes. The metallization patterns 112 may also be referred to as redistribution layers or redistribution lines. The metallization patterns 112 include metal lines and vias formed in one or more insulating layers 114. In some embodiments, the metallization patterns 112 may include a conductive material such as copper, silver, gold, tungsten, aluminum, combinations thereof, or the like, and may be formed through any acceptable process, such as a damascene process, a dual damascene process, or the like. In some embodiments, the redistribution structure 110 may include any number of insulating layers and metallization patterns.

After forming the redistribution structure 110, a plurality of conductive connectors 120 are formed on and in electrical contact with the redistribution structure 110. The conductive connectors 120 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 120 may include a conductive material such as solder, copper, aluminum, gold, nickel, silver, palladium, tin, the like, or a combination thereof. In some embodiments, the conductive connectors 120 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 120 comprise metal pillars (such as copper pillars) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

In some embodiments, the conductive connectors 120 comprise under-bump metallizations (UBMs) 120A and solder regions 120B over the UBMs 120A. The UBMs 120A may be conductive pillars, pads, or the like. In some embodiments, the UBMs 120A may be formed by forming a seed layer over the redistribution structure 110. The seed layer may be a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the UBMs 120A. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, nickel, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the UBMs 120A.

In some embodiments, the UBMs 120A may include three layers of conductive materials, such as a layer of titanium, a layer of copper, and a layer of nickel. Other arrangements of materials and layers, such as an arrangement of copper/nickel/copper, an arrangement of chrome/chrome-copper alloy/copper/gold, an arrangement of titanium/titanium tungsten/copper, or an arrangement of copper/nickel/gold, may be utilized for the formation of the UBMs 120A. Any suitable materials or layers of material that may be used for the UBMs 120A are fully intended to be included within the scope of the current application.

The solder regions 120B may comprise a solder material and may be formed over the UBMs 120A by dipping, printing, plating, or the like. The solder material may comprise, for example, lead-based and lead-free solders, such as Pb—Sn compositions for lead-based solder; lead-free solders including InSb; tin, silver, and copper (SAC) compositions; and other eutectic materials that have a common melting point and form conductive solder connections in electrical applications. For lead-free solder, SAC solders of varying compositions may be used, such as SAC 105 (Sn 98.5%, Ag 1.0%, Cu 0.5%), SAC 305, and SAC 405, as examples. Lead-free solders may further include SnCu compounds as well, without the use of silver (Ag). Lead-free solders may also include tin and silver, Sn—Ag, without the use of copper. In some embodiments, a reflow process may be performed, giving the solder regions 120B a shape of a partial sphere in some embodiments. In other embodiments, the solder regions 120B may have other shapes, such as non-spherical shapes.

After forming the conductive connectors 120, a cladding layer 122 is formed over the redistribution structure 110. In some embodiments, the cladding layer 122 covers the conductive connectors 120, so that top surfaces of the conductive connectors 120 are buried in the cladding layer 122. In some embodiments, a refractive index of the cladding layer 122 may be between about 1.0 and about 3.0, such as 1.56.

Referring to FIG. 1B, the cladding layer 122 is patterned to form a groove 125. In some embodiments, the groove 125 exposes the conductive connectors 120 and a portion of the redistribution structure 110. Specifically, the cladding layer 122 is patterned by using a gray tone mask. Since the light transmittance of the gray tone mask changes gradually and continuously, the groove 125 formed by the gray tone mask has inclined sidewalls 125s. From another perspective, the groove 125 is defined by the inner sidewalls 122s of the cladding layer 122. Accordingly, the inner sidewalls 122s of the cladding layer 122 are also inclined sidewalls. In some embodiments, an angle θ1 of the inclined sidewalls (e.g., 122s/125s) is about 40 degrees to 50 degrees. Selecting the angle θ1 of at least 40 degrees can prevent the flat top surface 122t of the cladding layer 122 too far away from the conductive connectors 120. The excessive distance will increase the width of the package structure, thereby reducing the usable area. Selecting the angle θ1 of no more than 50 degrees can avoid the hump issue of the to-be-formed core material 116 (FIG. 1C). That is, the large angle of the inclined sidewalls (e.g., 122s/125s) will cause the morphology issue for subsequently deposited layers. In some embodiments, the distance D1 between the cladding layer 122 and one of the conductive connectors 120 closest to the cladding layer 122 is greater than 40 μm. Selecting the distance D1 of at least 40 μm can prevent the subsequently formed optical glue 128 (FIG. 1E) in contact with the conductive connectors 120.

Referring to FIG. 1C, a core material 116 is formed over the redistribution structure 110. In some embodiments, the core material 116 conformally covers the conductive connectors 120, the sidewalls 122s and the top surface 122t of the cladding layer 122. Selecting the angle θ1 of no more than 50 degrees can avoid the hump issue of the core material 116 (as shown by the dotted line). In some embodiments, the core material 116 and the cladding layer 122 may have different refractive indexes. In some embodiments, a refractive index of the core material 116 may be between about 1.0 and about 3.0, such as 1.58. In detail, the core material 116 has a refractive index higher than the cladding layer 122. As such, the core material 116 with a rather high refractive index can be covered by the cladding layer 122 having a rather low refractive index, and an optical signal loss can be effectively reduced. It should be noted that, in the present embodiment, the difference (Δn) between the refractive index of the core material 116 and the refractive index of the cladding layer 122 is greater than 0 and less than or equal to 0.02, i.e., 0<Δn≤0.02. Selecting the range of the difference (Δn) can improve the optical coupling of the subsequently formed first waveguide structure 126 (FIG. 1D). In an embodiment, the core material 116 and the cladding layer 122 include a combination of polymer materials, such as poly(methylmethacrylate) (PMMA), polystyrene (PS), polycarbonate, polyurethane, benzocyclo butane, perfluorovinyl ether cyclopolymer, tetrafluoroethylene, perfluorovinyl ether copolymer, silicone, fluorinated poly(arylene ether sulfide, poly(pentafluorostyrene), fluorinated dendrimers, fluorinated hyperbranched polymers, or the like. In another embodiment, the core material 116 and the cladding layer 122 may comprise deuterated and halogenrate polyacrylates, fluorinated polyimides, perfluorocyclobutyl aryl ether polymers, nonlinear optical polymers, or the like.

Referring to FIG. 1C and FIG. 1D, a portion of the core material 116 is removed to form a first waveguide structure 126 on the cladding layer 122. Specifically, the first waveguide structure 126 may have a sloped top surface 126t1 adjacent to the groove 125, and a flat top surface 126t2 away from the groove 125. From a cross-sectional perspective, a thickness of the first waveguide structure 126 adjacent to the groove 125 is greater than a thickness of the first waveguide structure 126 away from the groove 125. From a top view, the first waveguide structure 126 may have a first portion 126A adjacent to the groove 125 and a second portion 126B away from the groove 125. As shown in the enlarged top view of FIG. 1D, the first portion 126A has a first width W1 or first area A1 greater than a second width W2 or first area A2 of the second portion 126B. The greater area A1 can improve the optical coupling and the alignment window between the first waveguide structure 126 and the second waveguide structure 72 in the subsequently bonded optical integrated circuit die 70 (FIG. 1E). In some embodiments, the distance D2 between the first waveguide structure 126 and one of the conductive connectors 120 closest to the first waveguide structure 126 is greater than 130 μm. Selecting the distance D2 of at least 130 μm can prevent the subsequently formed optical glue 128 (FIG. 1E) in contact with the conductive connectors 120.

Referring to FIG. 1E, a plurality of integrated circuit dies 50, 60 and 70 are attached to the redistribution structure 110. In some embodiments, the integrated circuit dies 50, 60 and 70 are bonded to the redistribution structure 110 by the conductive connectors 120. The integrated circuit dies 50, 60 and 70 may have the same or different functions from each other, as discussed in detail below.

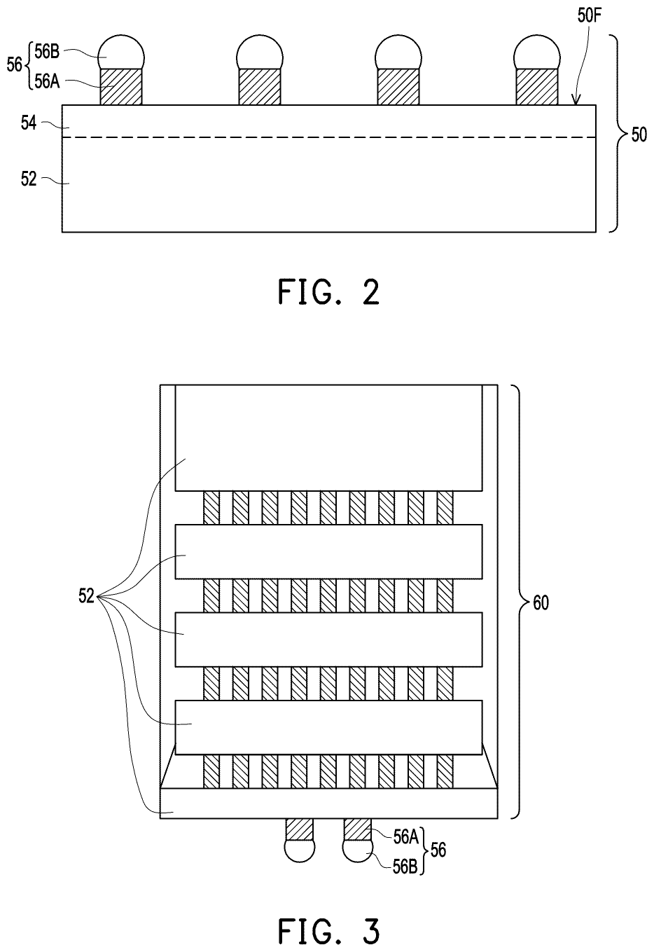

FIG. 2 illustrates a cross-sectional view of an exemplary integrated circuit die 50 in accordance with some embodiments. It is appreciated that the integrated circuit die 50 of FIG. 2 represents some of the possible structures of the integrated circuit die 50, but the embodiments of the present disclosure are not limited thereto. The integrated circuit die 50 will be packaged in subsequent processing to form integrated circuit packages. The integrated circuit die 50 may be a logic device (e.g., application-specific integrated circuit (ASIC) die, central processing unit (CPU), graphics processing unit (GPU), microcontroller, etc.), a memory device (e.g., dynamic random access memory (DRAM) die, static random access memory (SRAM) die, etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) dies), the like, or a combination thereof (e.g., a system-on-a-chip (SoC) die). The integrated circuit die 50 may be formed in a wafer, which may include different die regions that are singulated in subsequent steps to form a plurality of integrated circuit dies 50. The integrated circuit die 50 includes a semiconductor substrate 52, an interconnect structure 54, and conductive connectors 56.

The semiconductor substrate 52 may be a substrate of silicon, doped or undoped, or an active layer of a semiconductor-on-insulator (SOI) substrate. The semiconductor substrate 52 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The semiconductor substrate 52 has an active or a front-side surface (e.g., the surface facing upward) and an inactive or a backside surface (e.g., the surface facing downward). Devices are at the active surface of the semiconductor substrate 52. The devices may be active devices (e.g., transistors, diodes, etc.) and/or passive devices (capacitors, resistors, inductors, etc.). The inactive surface may be free from devices.

The interconnect structure 54 is over the active surface of the semiconductor substrate 52, and is used to electrically connect the devices of the semiconductor substrate 52 to form an integrated circuit. The interconnect structure 54 may include one or more dielectric layer(s) and respective metallization layer(s) in the dielectric layer(s). Acceptable dielectric materials for the dielectric layers include low-k dielectric materials such as phospho-silicate glass (PSG), boro-silicate glass (BSG), boron-doped phospho-silicate glass (BPSG), undoped silicate glass (USG), or the like. Acceptable dielectric materials for the dielectric layers further include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The metallization layers may include conductive vias and/or conductive lines to interconnect the devices of the semiconductor substrate 52. The metallization layers may be formed of a conductive material, such as a metal, such as copper, cobalt, aluminum, gold, combinations thereof, or the like. The interconnect structure 54 may be formed by a damascene process, such as a single damascene process, a dual damascene process, or the like.

A plurality of conductive connectors 56 are formed at the front-side 50F of the integrated circuit die 50. The conductive connectors 56 may comprise UBMs 56A and solder regions 56B over the UBMs 56A. The UBMs 56A may be formed using similar materials and methods as the UBMs 120A described above with reference to FIG. 1A, and the description is not repeated herein. The solder regions 56B may be formed using similar materials and methods as the solder regions 120B described above with reference to FIG. 1A, and the description is not repeated herein.

In some embodiments, the solder regions 56B may be used to perform chip probe (CP) testing on the integrated circuit die 50. For example, the solder regions may be solder balls, solder bumps, or the like, which are used to attach a chip probe to the conductive connectors 56. Chip probe testing may be performed on the integrated circuit die 50 to ascertain whether the integrated circuit die 50 is a known good die (KGD). Thus, only integrated circuit dies 50, which are KGDs, undergo subsequent processing and are packaged, and dies which fail the chip probe testing are not packaged. In some embodiments, after testing, the solder regions 56B may be removed in subsequent processing steps.

FIG. 3 illustrates a cross-sectional view of an exemplary integrated circuit die 60 in accordance with some embodiments. It is appreciated that the integrated circuit die 60 of FIG. 3 represents some of the possible structures of the integrated circuit die 60, but the embodiments of the present disclosure are not limited thereto. The integrated circuit die 60 is a stacked device that includes multiple semiconductor substrates 52. For example, the integrated circuit die 60 may be a memory device that includes multiple memory dies such as a hybrid memory cube (HMC) device, a high bandwidth memory (HBM) device, or the like. In such embodiments, the integrated circuit die 60 includes multiple semiconductor substrates 52 interconnected by through-substrate vias (TSVs) such as through-silicon vias (not shown). Each of the semiconductor substrates 52 may (or may not) have a separate interconnect structure.

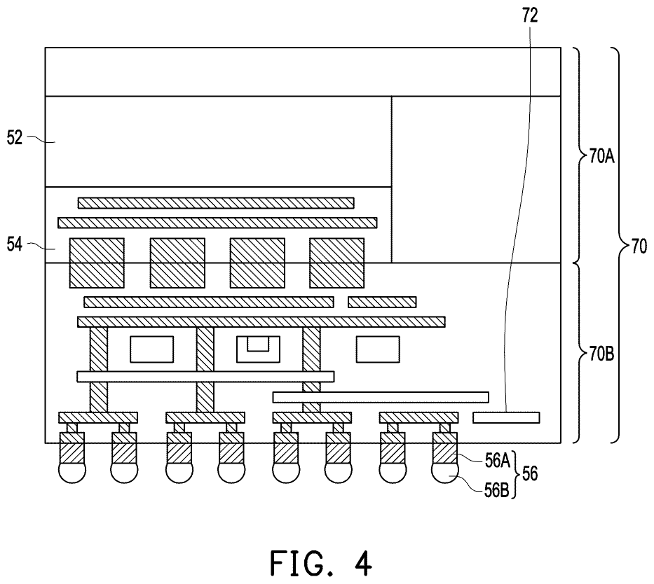

FIG. 4 illustrates a cross-sectional view of an exemplary integrated circuit die 70 in accordance with some embodiments. It is appreciated that the integrated circuit die 70 of FIG. 4 represents some of the possible structures of the integrated circuit die 70, but the embodiments of the present disclosure are not limited thereto. The integrated circuit die 70 may be an optical integrated circuit die, such as an optical engine die. The integrated circuit die 70 may include an electrical integrated circuit (EIC) 70A bonded to a photonic integrated circuit (PIC) 70B. The EIC 70A may comprise a semiconductor substrate 52, active and/or passive electric devices on the active side of the semiconductor substrate 52, and an interconnect structure 54 on the active side of the semiconductor substrate 52. The EIC 70A may be formed in a similar manner as the integrated circuit die 50 described above with reference to FIG. 2, and the description is not repeated herein. The PIC 70B may comprise optical devices, such as optical couplers, waveguides, modulators, or the like. The PIC 70B may also include an optical coupler, such as an edge coupler 72. In the present embodiment, the PIC 70B has a second waveguide structure 72 close to a sidewall (or an edge) 70E of the integrated circuit die 70. The second waveguide structure 72 may correspond to the first waveguide structure 126. The second waveguide structure 72 may include other photonic structures such as an edge coupler, that allow optical signals to be transmitted or processed. In some embodiments, the second waveguide structure 72 may comprise a dielectric material (such as, silicon nitride, or the like) and may be formed using physical vapor deposition (PVD), chemical vapor deposition (CVD), or the like. In other embodiments, the second waveguide structure 72 may comprise a semiconductor layer (such as, a silicon layer, or the like) and may be formed from an SOI substrate. The second waveguide structure 72 may provide optical coupling between the integrated circuit die 70 and the first waveguide structure 126.

The integrated circuit die 70 may be formed in a wafer, which may include different die regions that are singulated in subsequent steps to form a plurality of integrated circuit dies 70. In some embodiments, the wafer may be formed by hybrid bonding an EIC wafer (comprising a plurality of EICs 70A) to a PIC wafer (comprising a plurality of PICs 70B).

FIG. 1F illustrate the structure of FIG. 1E after formation an optical glue 128, in accordance with some embodiments. In some embodiment, the optical glue 128 includes a polymer material such as epoxy-acrylate oligomers. The polymer material may have a refractive index between about 1 and about 3. In some embodiments, the optical glue 128 is formed to cover a first sidewall 122s1 of the inclined sidewalls 122s, and extend to fill in a gap 127 between the sidewall 70E of the integrated circuit die 70 and the first waveguide structure 126. In addition, the optical glue 128 extends along and is in physical contact with the sidewall 70E of the integrated circuit die 70 and a portion of the top surface of the first waveguide structure 126. In some embodiments, the optical glue 128 completely covers the first sidewall 122s1 of the inclined sidewalls 122s directly under the integrated circuit die 70, while exposing a second sidewall 122s2 of the inclined sidewalls 122s opposite to the first sidewall 122s1. Further, the optical glue 128 may cover a portion of the bottom surface of the integrated circuit die 70, and does not contact the conductive connectors 120.

Referring to FIG. 1G, an underfill layer 130 is formed in the groove 125. In some embodiments, the underfill layer 130 is formed to laterally encapsulate the conductive connectors 120 to protect the conductive connectors 120 from thermal and mechanical stresses. In addition, the underfill layer 130 may extend along and is in physical contact with the surface of the optical glue 128 overlying the first sidewall 122s1 of the cladding layer 122, the gaps between the integrated circuit dies 50, 60 and 70, and a portion of the sidewall of the integrated circuit die 60.

Referring to FIG. 1H, an encapsulant 132 is formed in the groove 125 and further extends over the cladding layer 122. In some embodiments, the encapsulant 132 is formed to laterally encapsulate the underfill layer 130, the optical glue 128, and the integrated circuit dies 50, 60 and 70. In addition, the encapsulant 132 may extend along and is in physical contact with the second sidewall 122s2 of the cladding layer 122. The encapsulant 132 may be a molding compound, epoxy, or the like. The encapsulant 132 may not include fillers therein. The encapsulant 132 may be applied by compression molding, transfer molding, or the like, and is formed over the first carrier 100 so that the integrated circuit dies 50, 60 and 70 are buried or covered. The encapsulant 132 may be applied in liquid or semi-liquid form and then subsequently cured. The encapsulant 132 may be thinned to expose the integrated circuit dies 50, 60 and 70. The thinning process may be a grinding process, a CMP, an etch-back, combinations thereof, or the like. After the thinning process, top surfaces of the integrated circuit dies 50, 60 and 70, and the encapsulant 132 are coplanar (within process variations), so that they are level with one another. The thinning is performed until a desired amount of the integrated circuit dies 50, 60 and 70, and/or the encapsulant 132 has been removed. In some embodiments, a refractive index of the encapsulant 132 may be between about 1.5 and about 3.0.

Referring to FIG. 1H and FIG. 1I, a carrier swap process is performed. Specifically, the first carrier 100 is de-bonded from the overlying structure 150, so that the first carrier 100 is de-bonded from the encapsulant 108 and the dies 104. In some embodiments, the de-bonding process may also remove adhesives 106 from the dies 104. Subsequently, a second carrier 200 may be attached onto the integrated circuit dies 50, 60 and 70, and the encapsulant 132. The second carrier 200 may be formed using similar materials and methods as the first carrier 100 described above with reference to FIG. 1A, and the description is not repeated herein. In some embodiments, the overlying structure 150 is attached to the second carrier 200 by using an adhesive (not shown).

Referring to FIG. 1I and FIG. 1J, after attaching the second carrier 200 to the overlying structure 150, a redistribution structure 210 is formed on the backside 104bs of the LSI die 104A and a lower surface of the encapsulant 108. The redistribution structure 210 may include insulating layers and metallization patterns alternately disposed over the backside 104bs of the LSI die 104A and the lower surface of the encapsulant 108. The redistribution structure 210 may be formed using similar materials and methods as the redistribution structure 110 described above with reference to FIG. 1A, and the description is not repeated herein. In the present embodiment, the redistribution structure 110 may be referred to as a frontside redistribution structure 110; while the redistribution structure 210 may be referred to as a backside redistribution structure 210.

After forming the redistribution structure 210, a plurality of external connectors 220 are formed on the lower surface of the redistribution structure 210. The external connectors 220 may be electrically coupled to the conductive vias 102 and/or the dies 104 by the redistribution structure 210. The external connectors 220 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The external connectors 220 may be formed using similar materials and methods as the conductive connectors 120 described above with reference to FIG. 1A, and the description is not repeated herein. Then, the second carrier 200 is removed to expose the integrated circuit dies 50, 60, and 70, thereby accomplishing a package structure PK1.

As shown in FIG. 1J, the package structure PK1 may include a first tier 10, a second tier 20, and the cladding layer 122. The first tier 10 may have a first surface 10a and a second surface 10b opposite to each other. In some embodiments, the first tier 10 includes one or more dies 104, the encapsulant 108, the frontside redistribution structure 110, and the backside redistribution structure 210. The dies 104 laterally encapsulate by the encapsulant 108 are vertically sandwiched between the frontside redistribution structure 110, and the backside redistribution structure 210. In the present embodiment, the first tier 10 may be referred to as an interposer. The second tier 20 may be bonded to the second surface 10b of the first tier 10 by the conductive connectors 120. The cladding layer 122 may be vertically sandwiched between the first tier 10 and the second tier 20. The cladding layer 122 has the inner sidewalls 122s to define the groove (125 as marked in FIG. 1B) for accommodating the conductive connectors 120. The inner sidewalls 122s are inclined sidewalls. It should be noted that, in some embodiments, the tapered cladding layer 122 can control the deposition morphology of the core material 116 (FIG. 1C) to avoid the hump issue of the core material 116 (as shown by the dotted line in FIG. 1C). In some embodiments, the second tier 20 includes the integrated circuit dies 50, 60 and 70 disposed side-by-side. The optical integrated circuit die 70 may extend from the top surface of the cladding layer 122 to one of the conductive connectors 120 within the groove 125.

The package structure PK1 further includes the first waveguide structure 126, the optical glue 128, the underfill layer 130, and the encapsulant 132. The first waveguide structure 126 may be disposed on the cladding layer 122, and corresponding to the second waveguide structure 72 in the optical integrated circuit die 70. It should be noted that, in some embodiments, the first portion 126A adjacent to the sidewall 70E of the optical integrated circuit die 70 has a highest top surface higher than a highest top surface of the second portion 126B away from the sidewall 70E of the optical integrated circuit die 70. The tapered first waveguide structure 126 can improve the optical coupling and the alignment window between the first waveguide structure 126 and the second waveguide structure 72 in the optical integrated circuit die 70. From another perspective, the first area (A1 as shown in FIG. 1D) of the first waveguide structure 126 close to the sidewall 70E of the optical integrated circuit die 70 may be greater than the second area (A2 as shown in FIG. 1D) of the first waveguide structure 126 away from the sidewall 70E of the optical integrated circuit die 70. In addition, the optical glue 128 may cover the first sidewall 122s1 of the inner sidewalls 122s, and extend to fill in the gap 127 between the sidewall 70E of the optical integrated circuit die 70 and the first waveguide structure 126. In some embodiment, a tilted direction of the sloped top surface of the first waveguide structure 126 is different from a tilted direction of the inclined sidewall 122s1 of the cladding layer 122. The underfill layer 130 may laterally encapsulate the conductive connectors 120 and contacting the optical glue 128. The encapsulant 132 may laterally encapsulate the underfill layer 130 and the second tier 20. The package structure PK1 further includes the external connectors 220 formed on the first surface 10a of the first tier 10 for providing the external bonding.

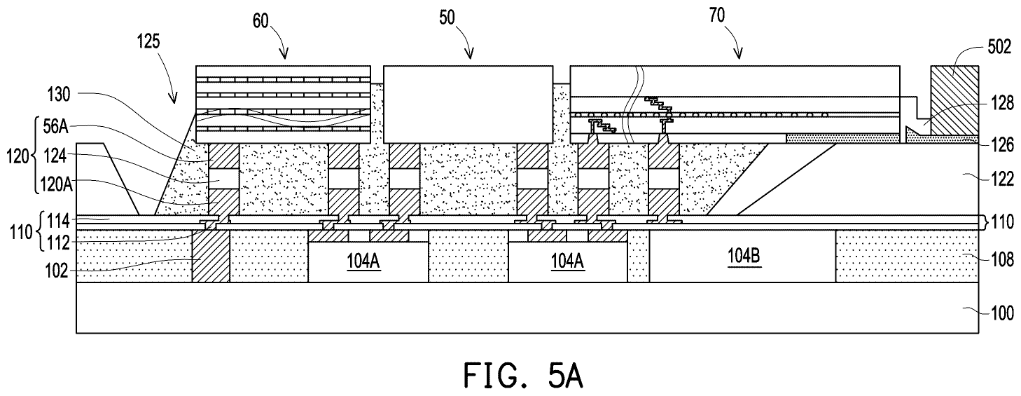

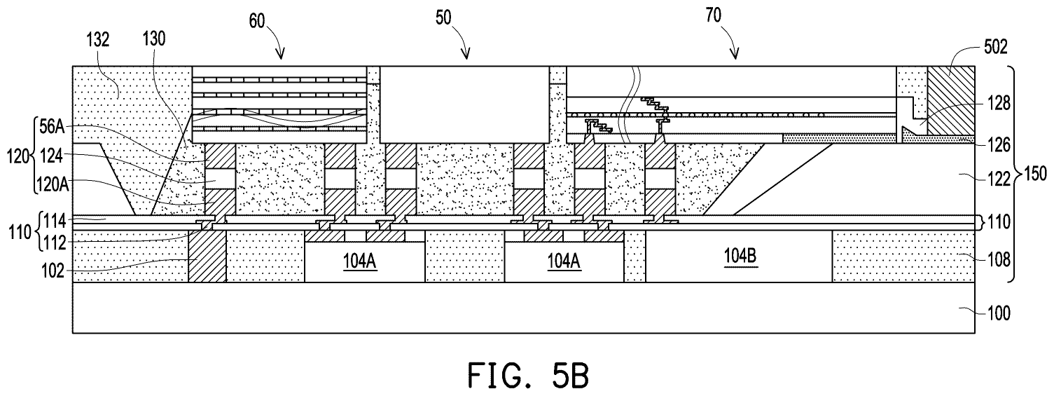

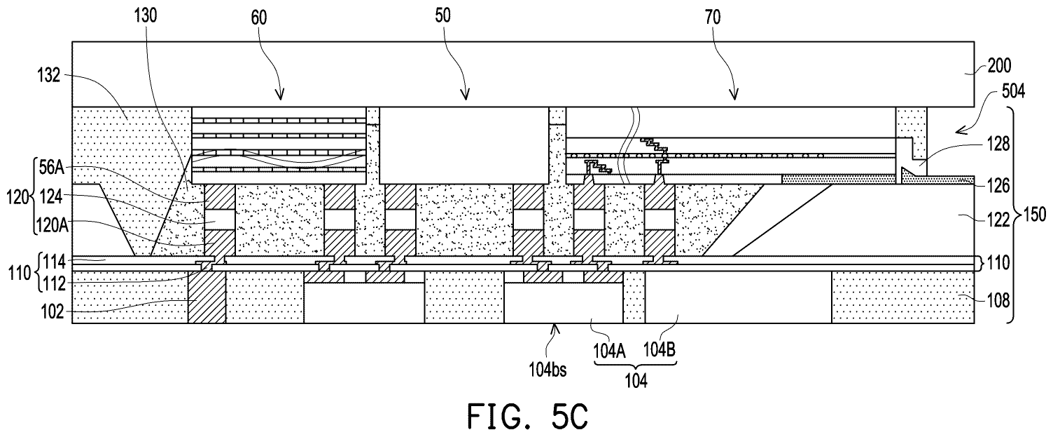

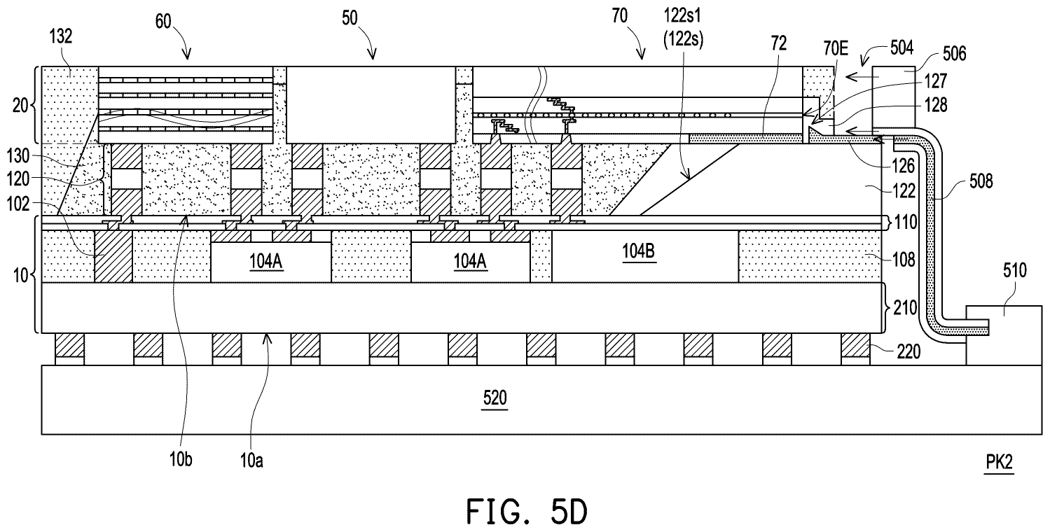

FIG. 5A to FIG. 5D illustrate cross-sectional views of intermediate stages in the formation of a package structure in accordance with some alternative embodiments.

FIG. 5A illustrates the fabrication by using the structure of FIG. 1G. After forming the structure of FIG. 1G, a sacrificial structure 502 is formed aside the optical integrated circuit die 70 on the first waveguide structure 126.

Referring to FIG. 5B, an encapsulant 132 is formed in the groove 125 and further extends over the cladding layer 122. In some embodiments, the encapsulant 132 is formed to laterally encapsulate the underfill layer 130, the optical glue 128, and the integrated circuit dies 50, 60 and 70. In addition, the encapsulant 132 may fill in a gap between the optical integrated circuit die 70 and the sacrificial structure 502 on the optical glue 128. The encapsulant 132 may be thinned to expose the integrated circuit dies 50, 60 and 70, and the sacrificial structure 502. The thinning process may be a grinding process, a CMP, an etch-back, combinations thereof, or the like. After the thinning process, top surfaces of the integrated circuit dies 50, 60 and 70, the sacrificial structure 502, and the encapsulant 132 are coplanar (within process variations), so that they are level with one another.

Referring to FIG. 5B and FIG. 5C, a carrier swap process is performed. Specifically, the first carrier 100 is de-bonded from the overlying structure 150, so that the first carrier 100 is de-bonded from the encapsulant 108 and the dies 104. In some embodiments, the de-bonding process may also remove adhesives 106 from the dies 104. Subsequently, a second carrier 200 may be attached onto the integrated circuit dies 50, 60 and 70, the sacrificial structure 502, and the encapsulant 132. After attaching the second carrier 200, the sacrificial structure 502 is removed to form a cavity 504. In some embodiments, the cavity 504 is between the second carrier 200 and the first waveguide structure 126 and exposes the surface of the first waveguide structure 126. In the present embodiment, the cavity 504 is configured to accommodate the subsequently joined fiber array unit 508 (FIG. 5D).

Referring to FIG. 5C and FIG. 5D, after attaching the second carrier 200 to the overlying structure 150, a redistribution structure 210 is formed on the backside 104bs of the LSI die 104A and a lower surface of the encapsulant 108. After forming the redistribution structure 210, a plurality of external connectors 220 are formed on the lower surface of the redistribution structure 210. The external connectors 220 may be electrically coupled to the conductive vias 102 and/or the dies 104 by the redistribution structure 210. In some embodiments, a circuit substrate 520 is bonded to the first surface 10a of the first tier 10 by the external connectors 220. Then, the second carrier 200 is removed to expose the integrated circuit dies 50, 60, and 70, thereby accomplishing a package structure PK2.

In some embodiments, the circuit substrate 520 includes a substrate core, which may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations thereof, or the like, may also be used. Additionally, the substrate core may be a SOI substrate. Generally, an SOI substrate includes a layer of a semiconductor material such as epitaxial silicon, germanium, silicon germanium, SOI, SGOI, or combinations thereof. In another embodiment, the substrate core is an insulating core such as a fiberglass reinforced resin core. One example core material is fiberglass resin such as FR4. Alternatives for the core material include bismaleimide-triazine (BT) resin, or alternatively, other printed circuit board (PCB) materials or films.

In some embodiments, the substrate core may include active and passive devices (not separately illustrated). Devices such as transistors, capacitors, resistors, combinations thereof, and the like may be used to generate the structural and functional requirements of the design for the system. The devices may be formed using any suitable methods. In some embodiments, the substrate core is substantially free of active and passive devices. In some embodiments, the substrate core further includes conductive vias, which may be also referred to as TSVs.

The circuit substrate 520 may also include a redistribution structure. In some embodiments, the redistribution structure may be formed of alternating layers of dielectric material (e.g., low-k dielectric material) and conductive material (e.g., copper) with vias interconnecting the layers of conductive material, and may be formed through any suitable process (such as deposition, damascene, or the like). In other embodiments, the redistribution structure may be formed of alternating layers of dielectric material (e.g., build up films such as Ajinomoto build-up film (ABF) or other laminates) and conductive material (e.g., copper) with vias interconnecting the layers of conductive material, and may be formed through any suitable process (such as lamination, plating, or the like).

In some embodiments, a fiber array unit 508 is attached to the package structure PK2 through the cavity 504. The fiber array unit 508 may provide an interface between the first waveguide structure 126 and a fiber connector 510 that is attached onto the circuit substrate 520 to achieve a detachable optical connection. In addition, a support structure 506 may be attached onto the fiber array unit 508 within the cavity 504.

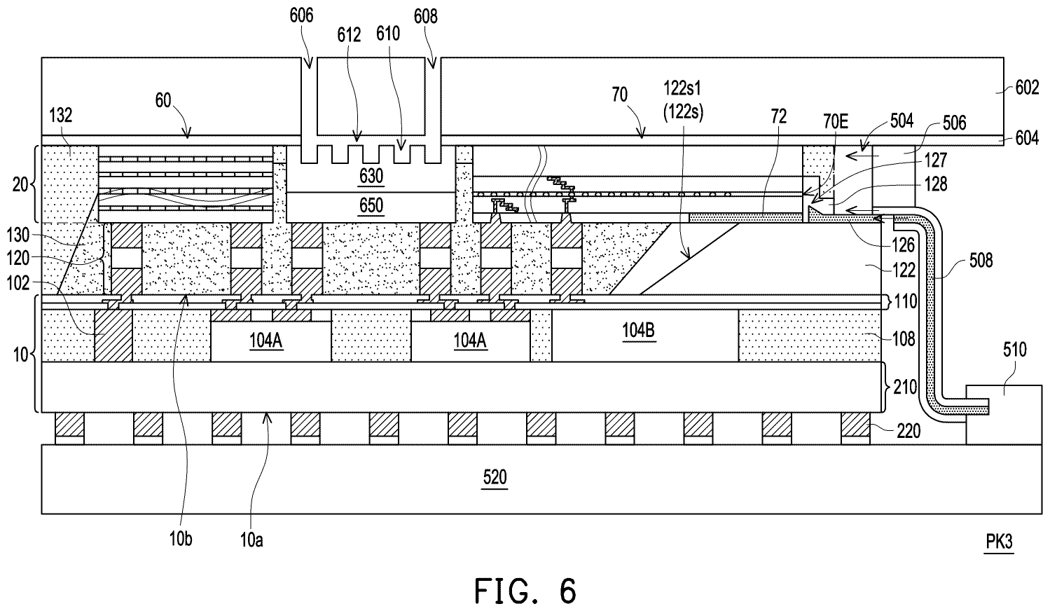

FIG. 6 illustrates a cross-sectional view of a package structure in accordance with some other embodiments.

Referring to FIG. 6, a package structure PK3 is similar to the package structure PK2 illustrated in FIG. 5D, but the integrated circuit die 50 is replaced by an integrated circuit die 650 having a heat dissipation structure 630 thereon. Specifically, the heat dissipation structure 630 may include a plurality of micro-channels 610 recessed from a top surface of the heat dissipation structure 630. The package structure PK3 further includes a lid 602 over the second tier 20. In some embodiments, the lid 602 is attached onto the integrated circuit dies 50, 60, and 70, and the encapsulant 132 by using an adhesive 604. The adhesive 604 may include a thermal interface material (TIM), such as a grease-based material, phase change material, gel, adhesive, polymeric, metallic material, or a combination thereof. In some embodiments, the TIM may include lead-tin based solder (PbSn), lead-free solder, silver paste (Ag), gold, tin, gallium, indium, carbon composite materials, graphite, carbon nanotubes, or other suitable thermally conductive materials.

In some embodiments, the lid 602 may extend over the micro-channels 610 to be separated from the micro-channels 610 by a non-zero distance. As shown in FIG. 6, the lid 602 further includes a first opening 606 and a second opening 608 extending through the lid 602. The lid 602 and the heat dissipation structure 630 may form a space 612 extending from the first opening 606 to the second opening 608.

In some embodiments, a cooling fluid may flow through one of the first opening 606 and the second opening 608, into the space 612 and the micro-channels 610, and out through the other one of the first opening 606 and the second opening 608. The first opening 606 and the second opening 608 may be disposed at any positions that can connect to the space 612 and may have any suitable quantities and shapes. The first opening 606 and the second opening 608 may be disposed adjacent to the micro-channels 610 and connect to the space 612. The first opening 606 and the second opening 608, the space 612, and the micro-channels 610 may be collectively referred to as a thermal dissipation pathway to provide further heat dissipation for the package structure PK3.

According to some embodiments, a package structure includes a first tier having a first surface and a second surface opposite to each other; a second tier bonding to the second surface of the first tier by a plurality of conductive connectors; and a cladding layer disposed between the first tier and the second tier, wherein the cladding layer has inner sidewalls to define a groove for accommodating the plurality of conductive connectors, and the inner sidewalls are inclined sidewalls.

According to some embodiments, a method of forming a package structure includes: forming an interposer on a first carrier, wherein the interposer has a first surface adjacent to the first carrier; forming a plurality of conductive connectors on a second surface of the interposer opposite to the first surface; forming a cladding layer on the second surface of the interposer, wherein the cladding layer covers the plurality of conductive connectors; patterning the cladding layer to from a groove exposing the plurality of conductive connectors, wherein the groove has inclined sidewalls; and bonding at least one optical integrated circuit die to the second surface of the interposer by a first portion of the plurality of conductive connectors.

According to some embodiments, a package structure includes a cladding layer sandwiched between an interposer and an optical integrated circuit die, wherein the cladding layer has an inclined sidewall; and a first waveguide structure disposed on the cladding layer, and corresponding to a second waveguide structure in the optical integrated circuit die, wherein the first waveguide structure has a sloped top surface adjacent to the optical integrated circuit die, and a tilted direction of the sloped top surface is different from a tilted direction of the inclined sidewall.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first tier having a first surface and a second surface opposite to each other;
a second tier bonding to the second surface of the first tier by a plurality of conductive connectors; and
a cladding layer disposed between the first tier and the second tier, wherein the cladding layer has inner sidewalls to define a groove for accommodating the plurality of conductive connectors, and the inner sidewalls are inclined sidewalls.

2. The package structure of claim 1, wherein an angle of the inclined sidewalls is about 40 degrees to 50 degrees.

3. The package structure of claim 1, wherein the second tier comprises at least one optical integrated circuit die, and the optical integrated circuit die extends from a top surface of the cladding layer to one of the plurality of conductive connectors within the groove.

4. The package structure of claim 3, further comprising:
a first waveguide structure disposed on the cladding layer, and corresponding to a second waveguide structure in the optical integrated circuit die; and
an optical glue covering a first sidewall of the inner sidewalls, and extending to fill in a gap between a sidewall of the optical integrated circuit die and the first waveguide structure.

5. The package structure of claim 4, wherein a first area of the first waveguide structure close to the sidewall of the optical integrated circuit die is greater than a second area of the first waveguide structure away from the sidewall of the optical integrated circuit die.

6. The package structure of claim 4, wherein the first waveguide structure comprises:
a first portion adjacent to the sidewall of the optical integrated circuit die; and
a second portion away from the sidewall of the optical integrated circuit die, wherein a highest top surface of the first portion is higher than a highest top surface of the second portion.

7. The package structure of claim 1, further comprising:
an underfill layer laterally encapsulating the plurality of conductive connectors and contacting the optical glue; and
an encapsulant laterally encapsulating the underfill layer and the second tier, and contacting a second sidewall of the inner sidewalls opposite to the first sidewall.

8. The package structure of claim 1, further comprising:
a cavity formed over the first waveguide structure and the cladding layer, wherein the cavity is configured to accommodate a fiber array unit; and
a circuit substrate bonding to the first surface of the first tier by a plurality of external connectors.

9. The package structure of claim 4, wherein:
the second tier further comprises an integrated circuit die, the integrated circuit die has a heat dissipation structure, the heat dissipation structure comprises a plurality of channels recessed from a top surface of the heat dissipation structure; and
the package structure further comprises a lid disposed on the second tier, wherein the lid extends over the plurality of channels.

10. The package structure of claim 9, wherein the lid comprises a first opening and a second opening extending through the lid, wherein the lid and the heat dissipation structure form a space extending from the first opening to the second opening.

11. A method of forming a package structure, comprising:
forming an interposer on a first carrier, wherein the interposer has a first surface adjacent to the first carrier;
forming a plurality of conductive connectors on a second surface of the interposer opposite to the first surface;
forming a cladding layer on the second surface of the interposer, wherein the cladding layer covers the plurality of conductive connectors;
patterning the cladding layer to from a groove exposing the plurality of conductive connectors, wherein the groove has inclined sidewalls; and
bonding at least one optical integrated circuit die to the second surface of the interposer by a first portion of the plurality of conductive connectors.

12. The method of claim 11, wherein before bonding the optical integrated circuit die to the second surface of the interposer, the method further comprises:
forming a first waveguide structure on the cladding layer, wherein the first waveguide structure corresponds to a second waveguide structure in the optical integrated circuit die.

13. The method of claim 12, wherein after bonding the optical integrated circuit die to the second surface of the interposer, the method further comprises:
forming an optical glue to cover a first sidewall of the inclined sidewalls, and extending to fill in a gap between a sidewall of the optical integrated circuit die and the first waveguide structure.

14. The method of claim 12, wherein a first area of the first waveguide structure close to the sidewall of the optical integrated circuit die is greater than a second area of the first waveguide structure away from the sidewall of the optical integrated circuit die.

15. The method of claim 12, further comprising:
forming an underfill layer to laterally encapsulate the plurality of conductive connectors;
forming a sacrificial structure aside the optical integrated circuit die on the first waveguide structure;
forming an encapsulant to laterally encapsulate the underfill layer and the optical integrated circuit die, and fill in a gap between the optical integrated circuit die and the sacrificial structure;
attaching a second carrier onto the optical integrated circuit die, the encapsulant, and the sacrificial structure;
removing the sacrificial structure to form a cavity, wherein the cavity is configured to accommodate a fiber array unit;
removing the first carrier to expose the first surface of the interposer; and
bonding a circuit substrate to the first surface of the interposer by a plurality of external connectors.

16. The method of claim 12, further comprising:
bonding an integrated circuit die to the second surface of the interposer by a second portion of the plurality of conductive connectors, wherein the integrated circuit die has a heat dissipation structure, the heat dissipation structure comprises a plurality of channels recessed from a top surface of the heat dissipation structure; and
forming a lid to cover the integrated circuit die and the optical integrated circuit die, wherein the lid extends over the plurality of channels,
wherein the lid comprises a first opening and a second opening extending through the lid, and the lid and the heat dissipation structure form a space extending from the first opening to the second opening.

17. A package structure, comprising:
a cladding layer sandwiched between an interposer and an optical integrated circuit die, wherein the cladding layer has an inclined sidewall; and
a first waveguide structure disposed on the cladding layer, and corresponding to a second waveguide structure in the optical integrated circuit die, wherein the first waveguide structure has a sloped top surface adjacent to the optical integrated circuit die, and a tilted direction of the sloped top surface is different from a tilted direction of the inclined sidewall.

18. The package structure of claim 17, wherein an angle of the inclined sidewall is about 40 degrees to 50 degrees.

19. The package structure of claim 17, further comprising: an optical glue covering the inner sidewalls, and extending to fill in a gap between a sidewall of the optical integrated circuit die and the first waveguide structure.

20. The package structure of claim 17, wherein a first area of the first waveguide structure close to a sidewall of the optical integrated circuit die is greater than a second area of the first waveguide structure away from the sidewall of the optical integrated circuit die.
